(19) United States
(12) Patent Application Publication
(10) Pub. No.: US 2007/0177433 A1
(43) Pub. Date: Aug. 2, 2007

(54) Method and system for data security of recording media

(76) Inventor: Jean-Francois Poirier, Deux-Montagnes (CA)

Correspondence Address: BERESKIN AND PARR, 40 KING STREET WEST, BOX 401, TORONTO, ON, M5H 3Y2, CA

(21) Appl. No.: 11/470,779

(22) Filed: Sep. 7, 2006

Related U.S. Application Data
(60) Provisional application No. 60/714,339, filed on Sep. 7, 2005.

(51) Int. Cl. G11C 7/10

(52) U.S. Cl. 365/189.05

(57) ABSTRACT

Described embodiments generally relate to methods of encoding data on a data storage medium and methods of decoding and reading such encoded data. Other aspects relate to systems or apparatus for performing these methods. Still other aspects relate to systems and methods for monitoring use of data recorded on data storage media. These aspects are particularly suited to protecting proprietary data against unauthorized or excessive copying, where the proprietary data is embodied on a data storage medium that is publicly available for rent or sale.

### CROSS-REFERENCE TO RELATED APPLICATIONS

The applications claims the benefit of U.S. Provisional Application Ser. No. 60/714,339, filed Sep. 7, 2005, the entire contents of which is hereby incorporated by reference.

### TECHNICAL FIELD

The described embodiments relate to a method and system for providing improved data security for recording media. In particular, the invention relates to a method and system for providing improved encryption of data stored on recording media and for monitoring use of the stored data.

### BACKGROUND

Certain data storage products, for example, such as optical media like compact discs (CDs) or digital video discs (DVDs), may contain data which is subject to copyright and it is therefore desirable to prevent unauthorized copying of such data. Conventional data protection measures are used in relation to some CDs or DVDs in an attempt to prevent unauthorized copying.

One example of such conventional protection measures is to add a secure sector to the optical disc that cannot be copied by normal CD/DVD writers. This secure sector contains information that will enable the disk to be read. Thus, unless the secure sector is also copied to the new disc, the new disc cannot be read. This protection technique will only be effective as long as the secure sector is not rewritable by available CD or DVD copiers. Similar problems may be encountered in protecting computer program instructions stored on data storage media.

Further, it is known to store data on recording media using data delimiters to identify sectors and blocks of data within which the payload data are stored. Such sectors and blocks use data delimiters in order to indicate to the reading device the start and end of a block or sector. If only the payload data is encrypted, a prospective copier can still use the data delimiters to readily identify the location of the payload data on the storage medium, which may assist the copier to decrypt the payload data.

It is desired to address or ameliorate one or more shortcomings or disadvantages associated with prior data security methods or systems for data storage media, or to at least provide a useful alternative to such prior methods or systems.

### SUMMARY

Described embodiments generally relate to methods of encoding data on a data storage medium and methods of decoding and reading such encoded data. Other aspects relate to systems or apparatus for performing these methods. Still other aspects relate to systems and methods for monitoring use of data recorded on data storage media. These aspects are particularly suited to protecting proprietary data against unauthorized or excessive copying, where the proprietary data is embodied on a data storage medium that is publicly available for rent or sale.

In one aspect, embodiments relate to a method of encoding data on a data storage medium. The method comprises the steps of: receiving a quantity of data to be stored on a data storage medium, the quantity of data including payload data and data delimiters; determining a unique identifier of the data storage medium; allocating an encoding key to the data storage medium, the encoding key being associated with the unique identifier; dividing the quantity of data into a plurality of data blocks of a predetermined size; encoding each data block using the encoding key to generate an encoded data block of the predetermined size; and storing all encoded data blocks on the data storage medium so that the quantity of data is stored on the data storage medium in encoded form.

The method may further include writing the unique identifier to the data storage medium, either in encoded or unencoded form.

The data storage medium may be an optical recording medium, such as an optical disc. The optical disc may be used for storage of audio and/or video data, for example. Alternatively, the optical disc may store other kinds of data, such as generic or specific data files or software program instructions. Other forms of data storage may be used, providing they can be written to at least once and can be read by a reading device.

The unique identifier may be a serial number of the optical recording medium. The step of determining may include reading the serial number from the optical recording medium. The encoding may include performing a logic operation on each data block, where the encoding key and the data block are operands of the logic operation. The encoding key may be a fixed key. Alternatively, the encoding key may be a variable key.

A variable key may be used to further encode the data blocks without further altering the predetermined size of the data blocks. The variable key encoding may be performed before or after the fixed key encoding. The variable key may vary for each data block. The variable key may depend, for example, on the location of the data block on the data storage medium. In another example, the variable key may be determined based on the fixed key or the unique identifier. The variable key may be determined from a series of numbers, optionally pseudo-random or random numbers, based on the fixed key or the unique identifier.

Another aspect relates to a data storage medium storing data encoded according to the method described above.

In another aspect, embodiments relate to a method of decoding encoded data stored on a data storage medium. The encoded data includes payload data and data delimiters. The method comprises:
a) providing a reading device for reading the data storage medium;
b) determining a first unique identifier of the data storage medium;
c) determining a second unique identifier of the reading device;
d) providing the first and second unique identifiers to a validation entity;
e) receiving a decryption code from the validation entity in response to step d);
f) reading the encoded data from the data storage medium; and
g) decoding the encoded data in data blocks of a predetermined size using the decryption code to generate decoded data blocks.

The method may further comprise buffering a plurality of the decoded data blocks, determining the payload data in the decoded data blocks based on the data delimiters and processing the payload data. Step f) may further comprise processing the encoded data using a first logic function and a first key specific to the reading device to generate intermediate encoded data. In such an embodiment, step g) may further comprise processing the intermediate encoded data using a second logic function and the encryption code to generate the decoded data blocks.

The first unique identifier may be, or be derived from, a serial number of the data storage medium and step b) may include reading the serial number from the data storage medium. The data storage medium may be an optical recording medium, such as an optical disc or any other kind of data storage medium.

The decryption code may be a fixed code. Alternatively, the decryption code may be a variable code. If the decryption code is a variable code, it may vary for each data block.

In another aspect of the decoding method, the data storage medium may be replaced with another data source, such as a data stream transmitted from another device.

A further aspect relates to a method of monitoring use of data stored on a data storage medium. The data is stored on a data storage medium using an encoding key and the data storage medium has a unique identifier. The method comprises the steps of: receiving a decryption key request from a data reading entity in relation to the data storage medium, the decryption key request including a reading device identifier and the unique identifier; determining a use number of the data storage medium based on the unique identifier; comparing the use number with a predetermined use limit of the data storage medium; and incrementing the use number if the use number is less than the predetermined use limit.

The method may further comprise storing the reading device identifier with the use number in a use record for the data storage medium. The method may further comprise the steps of: determining the encoding key based on the unique identifier; generating a decryption key based on the encoding key and the reading device identifier; and transmitting the decryption key to the data reading entity in response to the decryption key request.

The decryption key may be generated as an output of a logic function, where the encoding key and the reading device identifier are operands of the logic function. The unique identifier may be, or be derived from, a serial number of the data storage medium.

Embodiments may provide improved data security for data stored on data storage media, such as software, audio data on compact discs (CDs) and video data on digital video discs (DVDs), by encoding the data stored on the storage media with an encryption key that is known only to the entity that stores the data on the recording media. When a customer has purchased an encoded recording medium, for example; to play the audio and/or video files or read the software programs that are stored thereon, the customer must obtain a decryption key before being able to read the recording medium with the reading device. This may be done automatically by the reading device but may alternatively be done manually, for example, by telephone or by accessing a secure site over the Internet using a browser application.

The decryption key is only received from the validation entity in response to provision of a serial number of the device attempting to read the storage medium and an identifier of the storage medium itself. The decryption key is not the same as the encryption key. Rather, the decryption key is specific to the recording medium and the device reading the recording medium. Use of a variable key instead of, or in addition to, the fixed key advantageously provides for further improved security. If a variable key is used in the encoding, a corresponding variable key is used in the decryption process.

Because all of the bits on the recording medium are encoded, including data delimiters, it is not possible for prospective copiers to identify the beginning or end of the payload data when it is copied. Even if the recording medium is copied, it may not be readable because the data delimiters would not be apparent to the reading device.

Further, according to certain embodiments, the encoded data is read from the storage medium and is conditioned using a logic function to generate intermediate encoded data. However, this intermediate encoded data can not be decoded without receiving a decryption key from the validation entity. Thus, while a prospective copier may read the data stored on the storage medium, if the copier tries to generate a meaningful output from the intermediate encoded data, such output would only appear as noise. The decryption key provided by the validation entity in order to decrypt the intermediate encoded data is specific to the recording medium and to the reading device. The same key cannot be used to decrypt another recording medium which has the same original data stored on it as each recording medium uses a different encoding key. Similarly, the same key will not be valid for a different reading device.

A further aspect relates to a data processing device for an encrypted data storage medium. The data processing device comprises reading means for reading encrypted data stored on the data storage medium and a processor. The processor is in communication with the reading means for processing the encrypted data and controls the reading means. The processor has means for determining a first unique identifier of the data processing device and a second unique identifier of the data storage medium, and means for receiving a decryption code generated by a code provider based on the first and second unique identifiers. The processor is configured to decrypt the encrypted data based on the decryption code.

### BRIEF DESCRIPTION OF THE DRAWINGS

Embodiments are hereinafter described in further detail, by way of example only, with reference to the accompanying drawings, in which:

FIG. 1 is a block diagram of a system for reading encoded recording media;

FIG. 2 is a process flow diagram of a method of obtaining a decryption key for decrypting encrypted data stored on data storage media;

FIG. 3 is a process flow diagram of a method of decrypting encrypted data stored on data storage media;

FIG. 4 is a process flow diagram of a method of encrypting data and storing the data on data storage media; and

FIG. 5 is a block diagram of a system for reading encoded recording media.

### DETAILED DESCRIPTION

The described embodiments are suited to encoding data to be stored on data storage media, such as software, audio or video data, which, due to their vulnerability to piracy, require increased data security in order to limit or prevent unauthorized copying. For the purpose of illustration, some embodiments may be described with reference to an optical disc, as one example of data storage media. It should be understood, however, that the described embodiments may be applied to other forms of data storage media. Further, the encoding and decoding methods described herein may be employed alone or in combination with other encryption and decryption methods, such as may be known to persons skilled in the art.

The terms “encrypt” and “encode” and respective variations thereof are used interchangeably in this description. Similarly, the terms “decrypt” and “decode” and their variations are also used interchangeably.

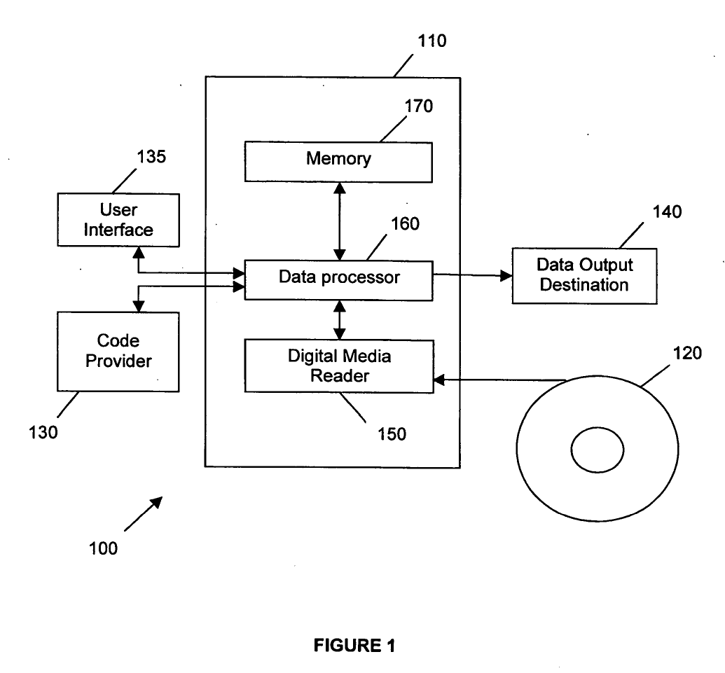

Referring now to the drawings, FIG. 1 is described in further detail. FIG. 1 is a block diagram of a system 100 for reading encoded recording media. The system 100 includes a reading device 110, such as an optical disc reader, a data storage medium 120, such as a compact disc or other form of rewritable non-volatile storage medium, and a code provider 130 located remotely from reading device 110. Reading device 110 has associated therewith a data output destination 140, which may be, for example, a computer processor or digital signal processor. For audio or video data, the digital signal processor may be in a television or other display having audio and video display capabilities in order that a customer can see and/or hear video and/or audio signals corresponding to the data stored on the data storage medium 120. The data output destination 140 may be any suitably secure data processing device.

Reading device 110 comprises a digital media reader 150 and a data processor 160. The digital media reader 150 is controlled by data processor 160 to read the data encoded on data storage medium 120 according to conventional means and provides the encoded data thus read to data processor 160 for decryption and processing according to its data type. As all of the data (including payload data and data delimiters) stored on data storage medium 120 is encoded, it must be read in blocks of one or more bytes and provided to data processor 160 for decryption before it can be processed and provided to data output destination 140.

Although all of the data stored on the data storage medium 120 is encoded, a serial number or other unique identifier of the data storage medium 120 is also stored thereon. The unique identifier is preferably unencoded, although it may alternatively be encoded. The unique identifier may be stored in a particular location on digital recoding medium 120, for example at the very beginning or end of the encoded data or in a special location, such as the inner circle of the disc, separate from the encoded data. In one embodiment, the unique identifier is readily readable by digital media reader 150. In an alternative embodiment, the unique identifier may be recorded on the data storage medium 120 so as to be visible to a person so that the person can manually enter the unique identifier through a user interface 135.

Data storage medium 120 may be of any suitable kind for storing data, including optical storage media, volatile and non-volatile memory devices, magnetic data storage media or any other mechanical, chemical, electrical or physical means of storing data, providing there is a suitable reading device, such as digital media reader 150, for reading the stored data. Specific examples of data storage medium 120 include optical discs, digital audio tapes (DATs) and memory cards or sticks. Embodiments of the invention are particularly useful in protecting data stored (pre-recorded) on commercially available data storage products.

In an alternative embodiment, data storage medium 120 may be replaced by a data source, such as a streaming or other data source. In one sense, data storage medium 120 may be generalized as one form of data source. In this context, the origin or form of storage of the data source is unimportant to the data processor 160, so long as data processor 160 can identify a unique identifier of the data source (to obtain the decryption code) and can process the data according to the format information in the decryption code.

Data processor 160 may be any suitable data processor having a speed and operating capacity to perform a series of logical operations in quick succession. For example, data processor 160 may have a data throughput efficiency suitable for handling data quantities in the order of several megabytes to several gigabytes.

Reading device 110 further comprises a memory 170, which may include flash memory or other read-only memory (ROM) and random access memory (RAM). As will be described in further detail below, memory 170 may store information on predetermined data formats and logic operations that may be used in the encoding and decoding. Memory 170 may be distinct from data processor 160, as shown in FIG. 1, or it may form a part of the architecture of data processor 160. The serial number or other unique identifier of the reading device 110 or data processor 160 (or both) is stored in memory 170. Alternatively, the serial number or other unique identifier may be stored in a memory internal to data processor 160, if memory 170 is separate from data processor 160.

Memory 170 may be encrypted (and decrypted) according to the methods described in co-owned and co-pending U.S. Utility patent application Ser. No. 11/350,839, filed Feb. 10, 2006, entitled “Method and System for Microprocessor Data Security”, the entire contents of which is hereby incorporated by reference.

System 100 further includes a user interface 135 in communication with data processor 160, either as part of a user interface provided by a device housing reading device 110 and operably associated therewith, or as a separate interface device, such as a remote control. If reading device 110 is part of a computer, such as a personal computer (PC) or server system, user interface 135 may be any known form of user interface, including, for example, a keyboard, mouse, display screen or other peripheral, allowing a user of the system 100 to interface with the reading device 110. Alternatively, depending on the form in which reading device 110 is embodied, user interface 135 may include other interface means, such as a small keypad and display, remote control or a two-way speech synthesizer.

Code provider 130 is preferably in communication with data processor 160 over a network, such as the Internet, where the reading device 110, or a host device housing reading device 110, is in connection with the network, either through a wired or wireless connection.

Code provider 130 is located remotely from reading device 110 and may be a computer system controlled by an entity responsible for monitoring use of the data storage medium 120 and for receiving requests for a decryption key to decrypt data stored on data storage media, such as data storage media 120. Code provider 130 also records the requests and the unique identifiers identified in the requests and thereby monitors the level of use of the data storage media 120.

Code provider 130 may allow fully automated data exchange with data processor 160. Alternatively, code provider 130 may accept decryption key requests through a form on a web page, an automated voice response (AVR) system or a call center operator, for example, and reply with the decryption key accordingly.

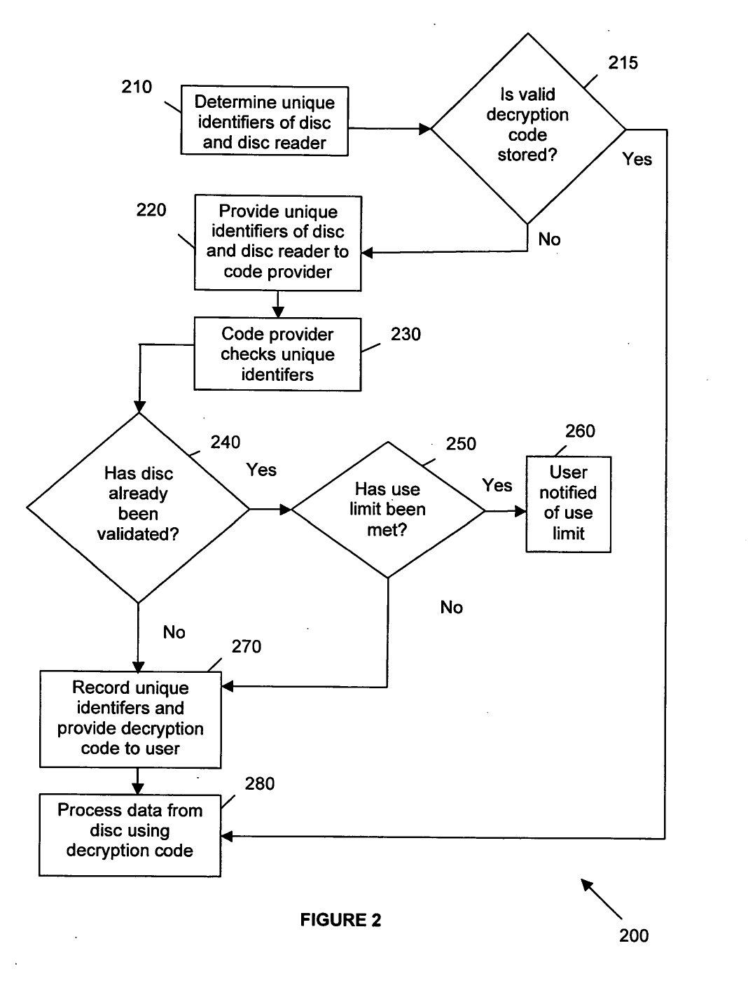

In response to requests for decryption keys, code provider 130 generates a decryption key based on the information provided in the request and transmits the decryption code, including a decryption key and any other relevant information for assisting decryption, to reading device 110. However, if the code provider 130 determines that the decryption code should not be provided in response to the request (as described below in relation to FIG. 2), code provider 130 transmits a notification to this effect to the user for display to the user through user interface 135.

In one embodiment, when the code provider 130 provides the decryption code to reading device 110, the decryption code has an expiry date associated therewith. Whether or not the decryption code has an expiry date, the decryption code is stored in memory 170 for subsequent use when decrypting the data encoded on data storage medium 120. The contents of the decryption code provided by code provider 130 is described in further detail below in relation to Tables 3A and 3B.

In one embodiment, a third party, such as a DVD (or other data) rental business, may request a time-limited decryption code from code provider 130 and the third party can then provide the received decryption code to the consumer, for example on a printed sheet, such as the rental receipt. This would require the consumer or rental business to provide the serial number or other identifier of reading device 110 when renting the DVD (or other data) so that the code provider 130 can generate an appropriate decryption code in response.

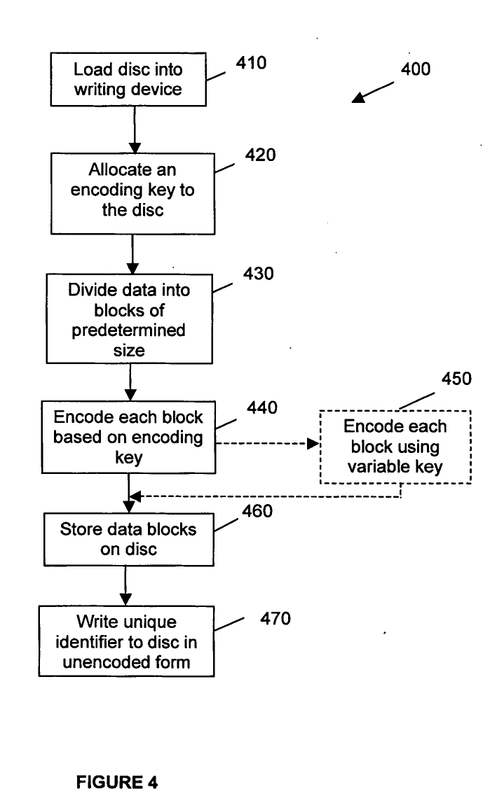

Referring now to FIG. 2, a method of obtaining a decryption key for decrypting encoded data stored on data storage media is described, the method being designated by reference indicator 200. Method 200 assumes that a data storage medium (encoded according to an embodiment of the invention, such as that described in relation to FIG. 4) has been inserted into a reading device, such as reading device 110. For purposes of illustration, method 200 is described by way of example with reference to an optical disc as the data storage medium 120.

Method 200 begins at step 210, in which digital media reader 150 determines the serial number or other unique identifier of the optical disc, either by reading it directly from the disc or by requesting a user to provide it via user interface 135. At this step, data processor 160 receives the unique identifier from digital media reader 150, if read from data storage medium 120, or from user interface 135, and accesses a unique identifier of the reading device 110 stored in memory 170. In an alternative embodiment, a unique identifier of data processor 160 may be provided instead of a unique identifier of reading device 110 as the basis for requesting the decryption code from code provider 130.

In step 215, data processor 160 checks whether a decryption code corresponding to the serial number of the data storage medium 120 has previously been received and, if so, whether the decryption code remains valid.

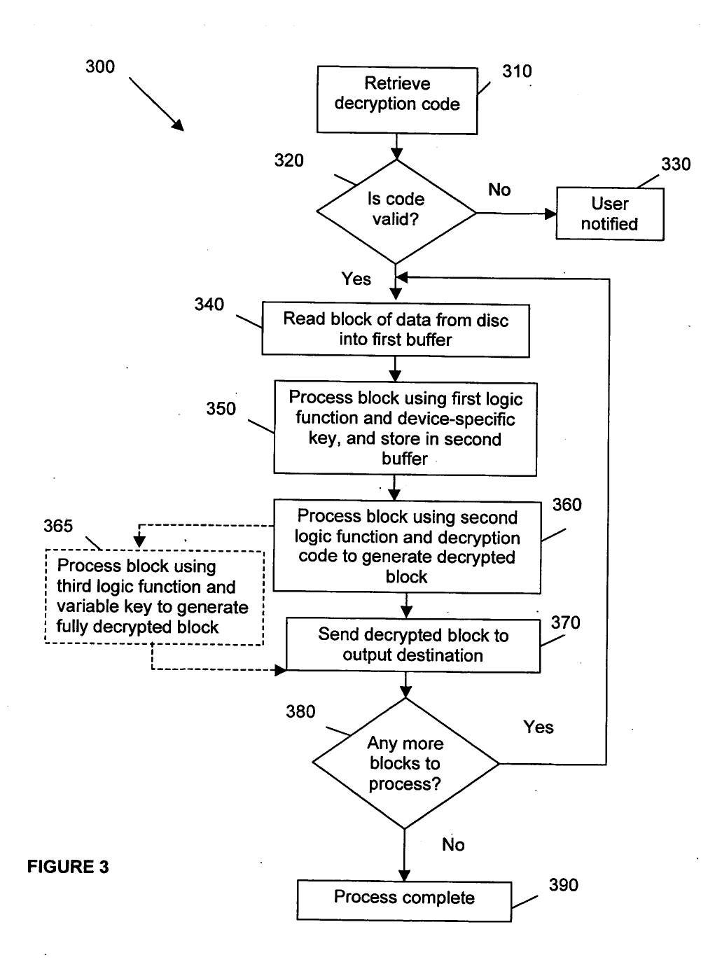

At step 220, if there is no decryption code stored for the particular data storage medium 120 being read, or if the stored code is no longer valid, data processor 160 provides the unique identifiers of the data storage medium 120 and reading device 100 (or data processor 160) to code provider 130 as part of a decryption key request. If data processor 160 is not in communication with code provider 130, the user is requested via user interface 135 to provide the unique identifiers to the code provider 130 in an alternative fashion, for example by telephone, and to retrieve a corresponding decryption code. If a valid decryption code is stored in memory 170, then following step 215 data processor 160 proceeds to process the encoded data stored on data storage medium 120 at step 280 to decrypt that data (according to the method described below in relation to FIG. 3) using the stored decryption code and provide the decrypted data to data output destination 140.

In step 220, data processor 160 preferably provides the unique identifiers in one or more data packets, which may be transmitted in encrypted form using, for example, a secure socket layer (SSL) protocol. Once code provider 130 receives the encryption key request packet, it parses the packet at step 230 to determine the unique identifiers of the storage medium 120 and reading device 100. Code provider 130 then uses the storage medium unique identifier to try to find a corresponding data record of the storage medium 120.

Once the data record for the storage medium 120 is located in a database (not shown) of the code provider 130, a use number, indicative of the number of times the particular storage medium 120 has been the subject of a valid decryption key request, is checked at step 240, to determine whether the storage medium 120 has previously been validated (i.e. the subject of a granted decryption key request). If, at step 240, it is determined that the storage medium 120 has been previously validated, the code provider 130 then compares the use number with a use limit at step 250.

If the use number is equal to the use limit, the storage medium 120 is determined to have been used its maximum number of times (i.e. by a maximum number of unique users) and the user is notified, at step 260, of the use limit by transmission of a return packet to data processor 160. The use limit may be any number determined by the entity controlling code provider 130 (or a copyright owner or licensee of the encoded data, if not the same entity) to constitute a reasonable limit on the number of different users corresponding to normal use of the storage medium 120. For example, for valuable software, the use limit may be a low number, such as 2 or 3, while for an audio CD, the use limit may be higher, such as 20 to 100.

If the storage medium 120 had not been previously validated or if the use limit has not been met, code provider 130 records the decryption key request, increments the use number and stores the unique identifier of the reading device 110 in the data record of the data storage medium 120, at step 270. As part of step 270, the code provider generates a decryption code, based on the unique identifiers of the data storage medium 120 and reading device 110 and sends the generated decryption code back to data processor 160, together with any relevant format information for the data processor 160 to determine how to decrypt the data encoded on data storage medium 120. The decryption code and format information is preferably provided to data processor 160 in one or more packets, which are preferably encrypted.

The format information, as will be described further in relation to Tables 3A and 3B, may include data indicative of one or more of a key validity condition, a variable key, an encoding logic function and a checksum. The format information may merely help the data processor 160 to determine that it has received the correct decryption code, for example, by checking the checksum, or it may be used to determine which logic functions to use in decrypting the stored data or how to determine the variable key (if used in the encoding process) necessary for decryption of the data.

The format information may specify different format codes corresponding to different formats. These format codes and the corresponding decryption formats are stored in memory 170 and are accessed by data processor 160 in response to receipt of the format information. The data processor 160 then uses the decryption formats corresponding to the specified format code when decoding the data on data storage medium 120.

Once data processor 160 has received the decryption code and format information, it proceeds, at step 280, to process the data read from the data storage medium 120 using the applicable decryption format determined from the format information.

Referring now to FIG. 3, there is shown a process flow diagram of a method of decrypting encrypted data stored on a data storage medium, the method being designated generally by reference numeral 300. Method 300 begins with step 310, at which the decryption code, including format information, is retrieved, for example according to method 200. At step 320, the decryption code is checked by data processor 160 for validity, for example using the checksum provided with the format information. Alternatively, there may be a validity condition associated with the decryption code, such as a limited time period during which the code is valid. If the code is determined not to be valid at step 320, the user may be notified via user interface 135 at step 330.

If the decryption code is determined to be valid, data processor 160 instructs digital media reader 150 to read a block of encoded data from the data storage medium 120 into a first buffer in memory 170, at step 340. The size of the data block read at step 340 may be the minimum block size used during the encoding. For example, if the data was encoded on a byte-by-byte basis, the encoded data blocks read at step 340 may be the size of a single byte. Alternatively, a multiple of the minimum block size may be read at step 340 so that a number of blocks are buffered together in the first buffer.

At step 350, the quantity of data read into the first buffer at step 340 is processed using a first logic function and a key specific to the reading device 100, which may be the unique identifier of the reading device 100. The key used in step 350 must be the same number or code as the unique identifier provided to the code provider 130 at step 220. Step 350 processes each data block (of minimum block size) separately according to the first logic function and the processed blocks are sequentially stored in a second buffer in memory 170.

Each data block is then processed at step 360, using a second logic function and the decryption code to generate a decrypted block. If the blocks were originally encoded using a variable key, each decrypted block generated at step 360 is only partially decrypted and undergoes further processing at step 365. Step 365 involves processing the partially decrypted blocks using a third logic function and the variable key to generate fully decrypted blocks. The fully decrypted blocks are then sent, at step 370, to data output destination 140 by data processor 160. At step 380, the data processor 160 checks whether any more blocks can be read from the data storage medium 120 for processing. If there are more blocks to be processed, steps 340 to 370 are repeated. Otherwise, the decryption process is determined by data processor 160 to be complete, at step 390.

In the above described embodiment, the blocks, or a number of the blocks, are read from the data storage medium 120 and processed in sequence. Alternatively, all data blocks may be read from the data storage medium and stored in the second buffer according to steps 340 and 350, with steps 360 to 370 being performed after step 380, so that the entire data contents of the data storage medium 120 is stored in the second buffer and is then processed block-by-block according to steps 360 to 370. In a further alternative, the data may be processed on a block-by-block basis, requiring only a single block to be stored, if necessary, at each processing stage.

The first, second and third logic functions used in steps 350, 360 and 365, respectively, may be any suitable logic function for translating or transposing bits within the data block. Such suitable logic functions may include, but are not limited to, the exclusive-OR (XOR) function, a hash function, addition, subtraction or bit shifting. The first, second and third logic functions may be different or the same and may comprise combinations of functions.

If a variable key was used in the encoding of data onto data storage medium 120, then step 365 is necessary in order to properly decode the data. If a variable key was used in the encoding, the format information received with the decryption code specifies the variable key that was used in the encoding. The format information received with the decryption code specifies the variable key format and a starting value so that the sequence of pseudo-random values making up the variable key can be reproduced.

In one embodiment, the variable key can be generated according to a seed value provided to a linear feedback shift register (LFSR) circuit within data processor 160. The sequence of pseudo-random values generated by the LFSR circuit in step 365 will be the same as those used in the encoding process, provided the same seed value is input into the LFSR circuit and the LFSR circuits on the encoding and decoding sides use the same tapping points. Instead of using an LFSR circuit to generate a pseudo-random number sequence, alternative methods of repeatably generating a number sequence may be used, resulting in either a pseudo-random number sequence or a non-random number sequence.

By reading the data from data storage medium 120 into a buffer and processing it using a key specific to the reading device 110 (such as its unique identifier), and receiving a decryption key from code provider 130 that is derived from the original encoding key used for the particular data storage medium 120 and a key specific to the reading device 100, the original encryption key used for the data storage medium 120 is never provided as such. Rather, the encryption key is used with the device specific key to generate, at code provider 130, a decryption key, which is then sent to data processor 160.

The application of the keys, and the transformation of the data using the keys, is illustrated in Table 1 below, using example data and key values for a data block size of one byte. Column 1 of Table 1 shows the original data prior to encryption, in hexadecimal and binary form. Column 2 shows the data of column 1 after it has been passed through an XOR function with key A and then saved on the data storage medium 120. Key A is the original encoding key, which is stored in the data record of the data storage medium 120 maintained in a database accessible to code provider 130. Key A may be numerically related to the serial number of the data storage medium 120 or it may be a random key value allocated to the data storage medium 120 and associated with its serial number in the data record.

TABLE 1

| | | Data Saved on | | Data Read by | | Decoded with | |
|---|---|---|---|---|---|---|---|
| | | Media | | Device | | Key | |
| | | Key A | Production | Key B | Player | Key C | Decoding |
| Original Data | | 5C | 01011100 | E5 | 11100101 | B9 | 10111001 |
| Original | Original | Disc | Disc | Player | Player | Final | Final |
| Data | Binary | Data | Binary | Data | Binary | Data | Binary |
| 2D | 00101101 | 71 | 01110001 | 94 | 10010100 | 2D | 00101101 |
| 3C | 00111100 | 60 | 01100000 | 85 | 10000101 | 3C | 00111100 |
| 4E | 01001110 | 12 | 00010010 | F7 | 11110111 | 4E | 01001110 |
| 2A | 00101010 | 76 | 01110110 | 93 | 10010011 | 2A | 00101010 |
| F4 | 11110100 | A8 | 10101000 | 4D | 01001101 | F4 | 11110100 |
| D6 | 11010110 | 8A | 10001010 | 6F | 01101111 | D6 | 11010110 |
| 54 | 01010100 | 08 | 00001000 | ED | 11101101 | 54 | 01010100 |
| 67 | 01100111 | 3B | 00111011 | DE | 11011110 | 67 | 01100111 |
| 8A | 10001010 | D6 | 11010110 | 33 | 00110011 | 8A | 10001010 |
| FE | 11111110 | A2 | 10100010 | 47 | 01000111 | FE | 11111110 |
| 7E | 01111110 | 22 | 00100010 | C7 | 11000111 | 7E | 01111110 |
| 8D | 10001101 | D1 | 11010001 | 34 | 00110100 | 8D | 10001101 |
| 56 | 01010110 | 0A | 00001010 | EF | 11101111 | 56 | 01010110 |
| 5B | 01011011 | 07 | 00000111 | E2 | 11100010 | 5B | 01011011 |
| B1 | 10110001 | ED | 11101101 | 08 | 00001000 | B1 | 10110001 |
| 1D | 00011101 | 41 | 01000001 | A4 | 10100100 | 1D | 00011101 |
| D4 | 11010100 | 88 | 10001000 | 6D | 01101101 | D4 | 11010100 |
| 04 | 00000100 | 58 | 01011000 | BD | 10111101 | 04 | 00000100 |
| F0 | 11110000 | AC | 10101100 | 49 | 01001001 | F0 | 11110000 |
| 30 | 00110000 | 6C | 01101100 | 89 | 10001001 | 30 | 00110000 |
| 0F | 00001111 | 53 | 01010011 | B6 | 10110110 | 0F | 00001111 |
| 1F | 00011111 | 43 | 01000011 | A6 | 10100110 | 1F | 00011111 |
| DE | 11011110 | 82 | 10000010 | 67 | 01100111 | DE | 11011110 |
| BA | 10111010 | E6 | 11100110 | 03 | 00000011 | BA | 10111010 |
| A0 | 10100000 | FC | 11111100 | 19 | 00011001 | A0 | 10100000 |
| 55 | 01010101 | 09 | 00001001 | EC | 11101100 | 55 | 01010101 |
| 44 | 01000100 | 18 | 00011000 | FD | 11111101 | 44 | 01000100 |
| 12 | 00010010 | 4E | 01001110 | AB | 10101011 | 12 | 00010010 |
| 00 | 00000000 | 5C | 01011100 | B9 | 10111001 | 00 | 00000000 |
| FF | 11111111 | A3 | 10100011 | 46 | 01000110 | FF | 11111111 |
| 45 | 01000101 | 19 | 00011001 | FC | 11111100 | 45 | 01000101 |
| 54 | 01010100 | 08 | 00001000 | ED | 11101101 | 54 | 01010100 |

| | | | |
|---|---|---|---|
| This is the original | The data is | The player reads | Key C is |
| data to be | encrypted using | the data with its | generated from |
| encrypted | Key A and then | device ID or | Key A and B then |
| COLUMN 1 | saved on the media | unique ID | used to find |
| | COLUMN 2 | COLUMN 3 | source |
| | | | COLUMN 4 |

Column 3 shows the data of column 2 when read into a buffer of reading device 110 and processed with key B using an XOR function. Key B is the unique identifier of the reading device 110 supplied to code provider 130 with the decryption key request. Column 4 shows the data of column 3 processed with key C using an XOR logic function, thereby generating the original data of column 1 l . Key C is the decryption key generated by code provider 130 from keys A and B using, in this example, an XOR logic function. Thus, in this example, key C equals key A XOR key B. Depending on the logic functions used in the encryption, the logic function used to generate key C from keys A and B may vary. This relationship may be generalized as C=f(A, B), where ( )is a logic function (which may itself be comprised of a combination of logic functions). Key C may then be used to obtain the original data using the logical inverse of f( ). In other words, if the data encoded using keys A and B is a function of the original data, the original data is obtained using key C by applying an inverse of that function to the encoded data.

Referring now to FIG. 4, a method of encoding a data storage medium is described in further detail and designated generally by reference numeral 400. Method 400 begins at step 410, at which the data storage medium 120 is loaded into, or otherwise connected with, a writing device so that data can be written to the data storage medium 120. Method 400 may, for example, be performed by code provider 130 or on behalf of the entity controlling code provider 130.

At step 420, an encoding key is allocated to the data storage medium 120 and associated with the serial number or other unique identifier of the data storage medium 120, if the encoding key is not the same as the serial number or other unique identifier.

At step 430, the data to be encoded on the data storage medium 120 is divided into blocks of a predetermined size. This size may be, for example, one byte or an integer multiple thereof. Alternatively, the block size may be a number of bits not divisible by 8.

At step 440, each block of data is encoded using the encoding key allocated at step 420. The bit length of the encoding key and data blocks are preferable the same. Step 440 involves performing a logic function on each data block using the encoding key to generate an encoded block. The logic function used in step 440 may any suitable logic function for which an inverse of the function can be used in decoding. Examples of suitable logic functions are described in relation to method 300 above.

Optionally, a variable key may also be used to encode each block, at step 450. In one embodiment, the encoding key allocated at step 420 and used in step 440 may be a variable key. However, in the embodiment of method 400 shown in FIG. 4, the variable key is separate to the encoding key, which is according to one preferred embodiment, a fixed key. If the encoding also uses a variable key, step 450 includes generating a sequence of numbers, which may be pseudo-random numbers, for use in the encoding. For each data block to be encoded, it is subjected to a further logic function using one of the sequence of numbers constituting the variable key to generate an encoded block, which is then stored on the data storage medium 120 at step 460. If the variable key encoding is not used, the encoded data blocks generated from step 440 are stored on the data storage medium 120 at step 460.

The sequence of numbers constituting the variable key may be a repeating sequence and may be pseudo-random. Importantly, the variable key must be repeatable, so that the same sequence used in the encoding can be generated during the decoding process. For this purpose, a starting value or seed value of the variable key is recorded together with the encoding key in the data record of the data storage medium 120. In one embodiment, the variable key may be generated using a LFSR circuit, such as is described and shown in U.S. application Ser. No. 11/350,839, using a particular seed value and having predetermined tapping points. In such a case, the configuration of the tapping points is also stored in the data record and transmitted with the seed value in the format information.

Once the encoded data blocks are stored on data storage medium 120, the unique identifier of the data storage medium is also written to the data storage medium 120 in an unencoded form, at step 470. For example, the unique identifier may be written to the start or end of the encoded data, using some form of data delimiter in order to separate the unique identifier from the encrypted data. Alternatively, the unique identifier may be written to a part of the data storage medium 120 not normally used for storing bulk data, so that it is stored separately to the encrypted data.

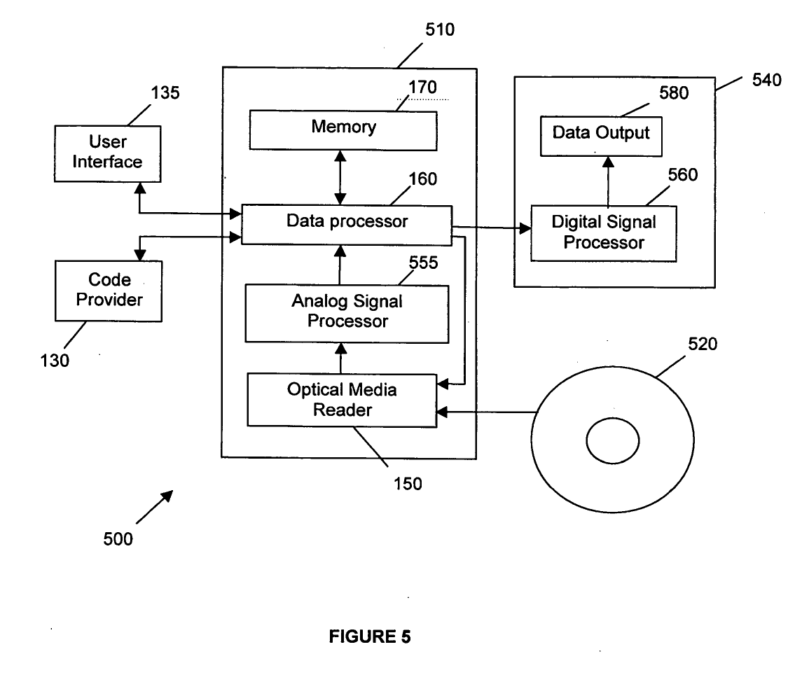

Referring now to FIG. 5, there is shown a block diagram of a system for reading encoded recording media according to another embodiment, designated generally by reference numeral 500. System 500 is a more specific example of the system 100 shown in FIG. 1, particularly suitable for reading data stored on optical media, such as an optical disc 520.

System 500 includes a reading device 510 that is similar to reading device 110, but has an analog signal processor 555 interposed between the optical media reader 150 and data processor 160. System 500 further includes an output device 540 for receiving data processed by reading device 510. Reading device 150 may be, for example, a computer having an optical disc drive, a video game console, a digital video disc player or an audio compact disc player. Output device 540 may be any suitable output device for receiving and processing the processed data from data processor 160, such as a computer processor, visual display and/or sound system.

In reading device 510, once optical media reader 150 converts the optical signals reflected from optical disc 520 into analog electrical signals, these analog signals are provided to analog signal processor 555, which converts the signals into a digital output to data processor 160. Data processor 160 treats this digital output as the encoded data stored on optical disc 520 and processes it as described previously. Data processor 160 controls optical media reader 150 to read the data stored on optical disc 520 according to known techniques. Similarly, optical media reader 150 and analog signal processor 555 read and process the data according to known techniques.

Output device 540 includes a digital signal processor 560 and a data output 580. If the output device 540 is a television or other visual display, for example, digital signal processor 560 will process the data stream output from data processor 160 and pass the processed data to data output 580 to display the video information. The form and function of digital signal processor 560 and data output 580 will depend on the form and function of output device 540, which may be any one of a number of visual, audio, audio-visual or other device that is designed to receive and output or store the received data.

In one embodiment of system 500, the data stream output from data processor 160 to digital signal processor 560 may be unencrypted. In an alternative embodiment of system 500, the data output from data processor 160 may be encrypted. If such encryption is used, it may be based upon a simple encryption scheme using a key known to the data processor 160, such as a serial number of data processor 160. For example, data processor 160 may encode the data that it has decrypted from optical disc 520 using a new key, and send the encoded data to digital signal processor 560.

In order for digital signal processor 560 to be able to decode the data from data processor 160, it must have received a decryption key corresponding (i.e. as a logical inverse) to the encryption key used by data processor 160 to encode the data. Accordingly, prior to transmitting the encoded data, data processor 160 transmits a decoding key to digital signal processor 560, which stores the key in memory (not shown).

The decoding key may be stored in the memory of digital signal processor 560 in a protected manner, such as is described in U.S. Utility patent application Ser. No. 11/350,839. Subsequent to receipt of the decoding key from data processor 160, digital signal processor 560 processes all incoming data using the decoding key. For this purpose, a simple logic function, such as an XOR or hash function, may be used, both at the data processor 160 during the encoding and at the digital signal processor 560 during the decoding. The digital signal processor 560 may store the decoding key (which is the logical inverse of the encoding key) permanently or until it is rewritten by data processor 160, for example using a specific key write command. Digital signal processor 560 may only accept a key rewrite command that specifies the previous key, to authenticate the command. In one embodiment, the decoding key may be entered through a user interface (not shown) associated with digital signal processor 560.

The encoding of data transmitted by data processor 160 to output device 540 advantageously causes the output device 540 to only be able to read data from reading device 510. In the example where reading device 510 is a DVD player and output device 540 is a television, this would have the effect that, if the television is stolen, it cannot be used by any DVD player other than that which uses the correct encoding key in transmitting its output signal to the television, thereby thwarting one possible purpose of the theft. This may serve as a disincentive to prospective thieves of televisions and other home entertainment equipment, including speakers.

Apart from the differences described above in relation to FIG. 500, memory 170, data processor 160, optical media reader 150, user interface 135 and code provider 130 operate in a similar manner to that described in relation to system 100 in FIG. 1.

With reference to Tables 2A and 2B below, encryption and decryption of data to and from data storage medium 120 or optical disc 520 using a variable key is described in further detail. As with column 1 of Table 1, column 1 in Table 2A shows the original data, prior to being encoded. Each of the columns of Tables 1, 2A and 2B show the data in hexadecimal form, as well as in binary form, using an example data block size of one byte for illustrative purposes. The keys used in the encryption and decryption are also one byte in the illustrated examples. The encryption and decryption keys are preferably, although not necessarily, the same size as the data blocks. It should be understood that the size of the data blocks and keys may vary depending on the requirements.

TABLE 2A
Process at the recording of the data

| | | | | | | Data Saved on | |
|---|---|---|---|---|---|---|---|
| | | Variable Key | | Intermediate Data | | Media | |
| | | LFSR | | Data XORed with | | Key A | Production |
| Original Data | | Seed | 0x08 | Variable LFSR Key | | 5C | 01011100 |
| | Original | LFSR | LFSR | Intermediate Data | | Stored | Stored |
| Original Data | Binary | KEY | Binary | HEX | Binary | Data | Binary |
| 2D | 00101101 | 08 | 00001000 | 25 | 00100101 | 79 | 01111001 |
| 3C | 00111100 | 03 | 00000011 | 3F | 00111111 | 63 | 01100011 |
| 4E | 01001110 | 06 | 00000110 | 48 | 01001000 | 14 | 00010100 |
| 2A | 00101010 | 0C | 00001100 | 26 | 00100110 | 7A | 01111010 |
| F4 | 11110100 | 0B | 00001011 | FF | 11111111 | A3 | 10100011 |
| D6 | 11010110 | 05 | 00000101 | D3 | 11010011 | 8F | 10001111 |
| 54 | 01010100 | 0A | 00001010 | 5E | 01011110 | 02 | 00000010 |
| 67 | 01100111 | 07 | 00000111 | 60 | 01100000 | 3C | 00111100 |
| 8A | 10001010 | 0E | 00001110 | 84 | 10000100 | D8 | 11011000 |
| FE | 11111110 | 0F | 00001111 | F1 | 11110001 | AD | 10101101 |
| 7E | 01111110 | 0D | 00001101 | 73 | 01110011 | 2F | 00101111 |
| 8D | 10001101 | 09 | 00001001 | 84 | 10000100 | D8 | 11011000 |
| 56 | 01010110 | 01 | 00000001 | 57 | 01010111 | 0B | 00001011 |
| 5B | 01011011 | 02 | 00000010 | 59 | 01011001 | 05 | 00000101 |
| B1 | 10110001 | 04 | 00000100 | B5 | 10110101 | E9 | 11101001 |
| 1D | 00011101 | 08 | 00001000 | 15 | 00010101 | 49 | 01001001 |
| D4 | 11010100 | 03 | 00000011 | D7 | 11010111 | 8B | 10001011 |
| 04 | 00000100 | 06 | 00000110 | 02 | 00000010 | 5E | 01011110 |
| F0 | 11110000 | 0C | 00001100 | FC | 11111100 | A0 | 10100000 |
| 30 | 00110000 | 0B | 00001011 | 3B | 00111011 | 67 | 01100111 |
| 0F | 00001111 | 05 | 00000101 | 0A | 00001010 | 56 | 01010110 |
| 1F | 00011111 | 0A | 00001010 | 15 | 00010101 | 49 | 01001001 |
| DE | 11011110 | 07 | 00000111 | D9 | 11011001 | 85 | 10000101 |
| BA | 10111010 | 0E | 00001110 | B4 | 10110100 | E8 | 11101000 |
| A0 | 10100000 | 0F | 00001111 | AF | 10101111 | F3 | 11110011 |
| 55 | 01010101 | 0D | 00001101 | 58 | 01011000 | 04 | 00000100 |
| 44 | 01000100 | 09 | 00001001 | 4D | 01001101 | 11 | 00010001 |
| 12 | 00010010 | 01 | 00000001 | 13 | 00010011 | 4F | 01001111 |
| 00 | 00000000 | 02 | 00000010 | 02 | 00000010 | 5E | 01011110 |
| FF | 11111111 | 04 | 00000100 | FB | 11111011 | A7 | 10100111 |
| 45 | 01000101 | 08 | 00001000 | 4D | 01001101 | 11 | 00010001 |
| 54 | 01010100 | 03 | 00000011 | 57 | 01010111 | 0B | 00001011 |

| | | | |
|---|---|---|---|
| This is the original | This is the data | This is the data | This data is encoded |
| data to be | generated by a | generated by XOR | using Key A and |
| encrypted | LFSR algorithm | of the first two | saved on the media |
| COLUMN 1 | (7 values) | columns | COLUMN 4 |
| | COLUMN 2 | COLUMN 3 | |

TABLE 2B
Process at the reading of the data

| Data Read by Device | | Decoded with Key C | | Decoded with Key | |
|---|---|---|---|---|---|
| Key B | Player | Key C | Decoding | Data XORed with | |
| E5 | 11100101 | B9 | 10111001 | Variable LFSR Key | |
| Player | Player | Intermediate Data | | Final | Final |
| Data | Binary | Data | Binary | Data | Binary |
| 9C | 10011100 | 25 | 00100101 | 2D | 00101101 |
| 86 | 10000110 | 3F | 00111111 | 3C | 00111100 |
| F1 | 11110001 | 48 | 01001000 | 4E | 01001110 |
| 9F | 10011111 | 26 | 00100110 | 2A | 00101010 |
| 46 | 01000110 | FF | 11111111 | F4 | 11110100 |
| 6A | 01101010 | D3 | 11010011 | D6 | 11010110 |
| E7 | 11100111 | 5E | 01011110 | 54 | 01010100 |
| D9 | 11011001 | 60 | 01100000 | 67 | 01100111 |
| 3D | 00111101 | 84 | 10000100 | 8A | 10001010 |
| 48 | 01001000 | F1 | 11110001 | FE | 11111110 |
| CA | 11001010 | 73 | 01110011 | 7E | 01111110 |
| 3D | 00111101 | 84 | 10000100 | 8D | 10001101 |
| EE | 11101110 | 57 | 01010111 | 56 | 01010110 |
| E0 | 11100000 | 59 | 01011001 | 5B | 01011011 |
| 0C | 00001100 | B5 | 10110101 | B1 | 10110001 |
| AC | 10101100 | 15 | 00010101 | 1D | 00011101 |
| 6E | 01101110 | D7 | 11010111 | D4 | 11010100 |
| BB | 10111011 | 02 | 00000010 | 04 | 00000100 |
| 45 | 01000101 | FC | 11111100 | F0 | 11110000 |
| 82 | 10000010 | 3B | 00111011 | 30 | 00110000 |
| B3 | 10110011 | 0A | 00001010 | 0F | 00001111 |
| AC | 10101100 | 15 | 00010101 | 1F | 00011111 |
| 60 | 01100000 | D9 | 11011001 | DE | 11011110 |
| 0D | 00001101 | B4 | 10110100 | BA | 10111010 |
| 16 | 00010110 | AF | 10101111 | A0 | 10100000 |
| E1 | 11100001 | 58 | 01011000 | 55 | 01010101 |
| F4 | 11110100 | 4D | 01001101 | 44 | 01000100 |
| AA | 10101010 | 13 | 00010011 | 12 | 00010010 |
| BB | 10111011 | 02 | 00000010 | 00 | 00000000 |
| 42 | 01000010 | FB | 11111011 | FF | 11111111 |
| F4 | 11110100 | 4D | 01001101 | 45 | 01000101 |
| EE | 11101110 | 57 | 01010111 | 54 | 01010100 |

| | | |
|---|---|---|
| The player reads the | Key C is generated | The data is XORed |
| data with its device ID | from Key A and B then | back with the LFSR |
| or unique ID (Key B) | XORed with data read | table to find the data |
| COLUMN 5 | COLUMN 6 | COLUMN 7 |

Column 2 of Table 2A shows a variable key generated by an LFSR circuit, based on an example seed value of 8 and a particular tapping configuration. Column 3 shows the original data encoded with the variable key value using an XOR function. The data of column 3 is then further encoded with a fixed key (key A) using an XOR function and stored on the data storage medium 120 in the form shown in column 4.

Column 5 (Table 2B) shows the data of column 4 as read by reading device 110 or 510, using key B, which is the unique identifier of the reading device 110 or 510. Once the decoding key C is received from code provider 130, the data of column 5 is processed using key C and an XOR function, to generate the intermediately decoded data shown in column 6. The data of column 6 is then processed using the variable key values of column 2 and an XOR function to generate the fully decoded data shown in column 7, which is the same as the original data shown in column 1. While the logic functions used in this example are all XOR functions, it should be understood that other suitable functions may be used in the encoding and decoding processes, providing the encoding logic functions have suitable inverse functions for the decoding process.

While Tables 2A and 2B show an example of data encoding and decoding using a fixed key in combination with a variable key, alternative embodiments may use only a variable key or may use two or more fixed or variable keys instead of a combination.

In Tables 3A and 3B below, examples of format information comprised in the decryption code are illustrated. In Table 3A, examples of format information are shown, as examples 1 and 2, for the case where the format information includes a key lifetime value, for example as a number of hours. The lifetime value indicates the time during which the decryption key transmitted with the format information is valid. Once the key lifetime expires, the decryption key becomes unusable by reading device 110 or 510.

TABLE 3A
Examples of key with time out value

| Validation | Key | Seed | Key | | |
|---|---|---|---|---|---|
| Checksum | Format | Value | Life (hours) | | |
| 005BDE | 00 | 5BA2 | 003C | | Example 1 |
| 23518 | 0 | 23458 | 60 | | |
| Key Value: | | | 2 | Days | |
| 23518, 0, 23458, 60 | | | 12 | Hours | |
| Validation | Key | Seed | Key | | |
| Checksum | Format | Value | Life (hours) | | |
| 01224E | 00 | FFFF | 224F | | Example 2 |
| 74318 | 0 | 65535 | 8783 | | |
| Key Value: | | | 365 | Days | |

| | | |
|---|---|---|
| 74318, 0, 65535, 8783 | 23 | Hours |

The first 3 bytes is the checksum of the whole packet
The next 2 bytes is the seed for the LFSR in the player
The last 2 bytes is the number of hours the disc is allowed to play
The key life can be computed from the number of days and hours
The key can be entered in an encoded format with digits 0 to 9

TABLE 3B
Examples of key with start & end date

| | Key | | First | | Last | | |
|---|---|---|---|---|---|---|---|
| Validation | For- | Seed | Valid | | Valid | | |
| Checksum | mat | Value | Date | | Date | | |
| 005EC9 | 01 | 5BA2 | 0193 | | 0194 | | Exam- |
| 24265 | 1 | 23458 | 403 | | 404 | | ple 3 |
| | | | 31 | Date | 1 | Date | |
| Key | | | 12 | Month | 1 | Month | |
| Value: | | | | | | | |
| 24265, 1, 23458, | | | 2005 | Year | 2006 | Year | |
| 403, 404 | | | | | | | |
| | Key | | First | | Last | | |
| Validation | For- | Seed | Valid | | Valid | | |
| Checksum | mat | Value | Date | | Date | | |
| 01BA3E | 01 | FFFF | 0020 | | BA1F | | Exam- |
| 113214 | 1 | 65535 | 32 | | 47647 | | ple 4 |
| | | | 1 | Date | 31 | Date | |
| Key | | | 1 | Month | 12 | Month | |
| Value: | | | | | | | |

| | | | | |
|---|---|---|---|---|
| 113214, 1, 65535, | 2005 | Year | 2132 | Year |
| 32, 47647 | | | | |

The first 3 bytes is the checksum of the whole packet
The next 2 bytes is the seed for the LFSR in the player
The next 2 bytes is the starting day (in days from a particular date) the disc is allowed to play
The last 2 bytes is the date when the player stops being authorized to read the disc
The key can be entered in an encoded format with digits 0 to 9

In the examples illustrated in Tables 3A and 3B, the format information includes a validation checksum for checking whether the encryption key and format information may have been corrupted, for example during transmission from the code provider 130. Further, the format information includes a key format code, which the reading device 110 or 510 uses to determine (according to a stored reference table in memory 170) which logic functions and decoding methods to use and the decoding process. For example, the key format code may specify a format that uses a combination of XOR functions and hash functions and specifies that an LFSR circuit is to be used to generate a pseudo-random number sequence based on a seed value transmitted with the format information. In another example, the key format code may specify a format that does not employ variable key decoding or that does not specify a key lifetime. Accordingly, the key format code will dictate whether the variable key seed value or key lifetime value is necessary for the decoding process.

In table 3B, two examples of format information are shown as Examples 3 and 4, where the format information includes a specified validity period of the decryption key, including a start and end date during which the decryption key is valid. The format information in these examples also includes a validation checksum, a format code and a seed value.

In one embodiment, the data block size may be varied in the encoding process. For example, a pseudo-random or non-random number sequence may be used to determine the block size of each data block. If the number sequence is pseudo-random, an LFSR circuit may be used to generate the number sequence. During decoding, the same pseudo-random or non-random number sequence is used to determine the data block size. If the encoding process used varying data block sizes, this is indicated by the format code transmitted with the decryption code and the format information includes a seed value for generating the appropriate number sequence.

Embodiments are described above in relation to the Figures and Tables. It should be understood that these embodiments are provided by way of example only and that some variation or modification of the features and/or elements of the embodiments may be made without departing from the spirit and scope of the described embodiments, and all such variations and beneficiations are included within that scope.

1. A method of encoding data on a data storage medium, comprising:
receiving a quantity of data to be stored on the data storage medium, the quantity of data including payload data and data delimiters;
determining a unique identifier of the data storage medium;
allocating an encoding key to the data storage medium, the encoding key being associated with the unique identifier;
dividing the quantity of data into a plurality of data blocks of a predetermined size;
encoding each data block using the encoding key to generate an encoded data block of the predetermined size; and
storing all encoded data blocks on the data storage medium so that the quantity of data is stored on the data storage medium in encoded form.

2. The method of claim 1, wherein the data storage medium is an optical recording medium.

3. The method of claim 1, wherein the step of determining includes reading the unique identifier from the data storage medium.

4. The method of claim 1, wherein the encoding includes performing a logic operation on each data block, where the encoding key and the data block are operands of the logic operation.

5. The method of claim 1, wherein the predetermined size is one byte.

6. The method of claim 1, wherein the encoding key is a fixed key.

7. The method of claim 6, further comprising, prior to the step of storing, further encoding each data block using a variable key to generate a further encoded data block of the predetermined size.

8. The method of claim 6, further comprising, after the step of allocating and before the step of encoding, partially encoding each data block using a variable key to generate a partially encoded data block of the predetermined size.

9. The method of claim 7, wherein the variable key varies for each data block.

10. The method of claim 7, wherein the variable key is determined based on the fixed key or the unique identifier.

11. The method of claim 7, wherein the variable key is a repeatably generated pseudo-random number.

12. The method of claim 11, wherein a linear feedback shift register is used to generate the variable key, based on a predetermined seed value.

13. A method of decoding encoded data stored on a data storage medium, the encoded data including payload data and data delimiters, the method comprising:
a) providing a reading device for reading the data storage medium;
b) determining a first unique identifier of the data storage medium;
c) determining a second unique identifier of the reading device;
d) providing the first and second unique identifiers to a validation entity;
e) receiving a decryption code from the validation entity in response to step d);
f) reading the encoded data from the data storage medium; and
g) decoding the encoded data in data blocks of a predetermined size using the decryption code to generate decoded data blocks.

14. The method of claim 13, further comprising:
h) buffering a plurality of the decoded data blocks;
i) determining the payload data in the decoded data blocks based on the data delimiters; and
j) processing the payload data.

15. The method of claim 13, wherein step f) further comprises processing the encoded data using a first logic function and a first key specific to the reading device to generate intermediate encoded data and step g) further comprises processing the intermediate encoded data using a second logic function and the decryption code to generate the decoded data blocks.

16. The method of claim 13, wherein the data storage medium is an optical recording medium.

17. The method of claim 13, wherein step b) includes reading the unique identifier from the data storage medium.

18. The method of claim 13, wherein the decryption code comprises a fixed code.

19. The method of claim 13, wherein the decryption code comprises a variable code.

20. The method of claim 19, wherein the variable code varies for each data block.

21. The method of claim 13, wherein the decryption code includes a fixed code and a variable code.

22. The method of claim 19, wherein the variable code is used to generate a sequence of keys for decoding the encoded data.

23. The method of claim 22, wherein each of the keys in the sequence of keys is used to decode a respective data block.

24. The method of claim 22, wherein the variable code includes a seed value and a linear feedback shift register (LFSR) is used to generate the sequence of keys based on the seed value.

25. A method of monitoring use of data stored on a data storage medium using an encoding key, the data storage medium having a unique identifier, the method comprising:
receiving a decryption key request from a data reading entity in relation to the data storage medium, the decryption key request including a reading device identifier and the unique identifier;
determining a use number of the data storage medium based on the unique identifier;
comparing the use number with a predetermined use limit of the data storage medium; and
incrementing the use number if the use number is less than the predetermined use limit.

26. The method of claim 25, further comprising storing the reading device identifier with the use number in a use record of the data storage medium.

27. The method of claim 25, further comprising the steps of:
determining the encoding key based on the unique identifier;
generating a decryption key based on the encoding key and the reading device identifier; and
transmitting the decryption key to the data reading entity in response to the decryption key request.

28. The method of claim 25, wherein the decryption key is generated as an output of a logic function and the encoding key and the reading device identifier are operands of the logic function.

29. The method of claim 25, wherein the unique identifier is, or is derived from, a serial number of the data storage medium.

30. The method of claim 27, where the step of transmitting includes transmitting format information with the decryption key, the format information being indicative of an encoding format used to encode the data stored on the data storage medium.

31. The method of claim 30, wherein the format information includes data indicative of at least one of a key validity condition, a variable key, an encoding logic function and a checksum.

32. The method of claim 31, wherein the variable key comprises a seed value for generating a pseudo-random number sequence as the variable key.

33. The method of claim 32, wherein a linear feedback shift register (LFSR) is used to generate the pseudo-random number sequence based on the seed value.

34. The method of claim 31, wherein the key validity condition includes a key validity period.

35. A data processing device for an encrypted data storage medium, the device comprising:
a reader for reading encrypted data stored on the data storage medium; and
a processor in communication with the reader for processing the encrypted data and controlling the reader, the processor being configured to determine a first unique identifier of the data processing device and a second unique identifier of the data storage medium, and to receive a decryption code generated by a code provider based on the first and second unique identifiers, the processor being further configured to decrypt the encrypted data based on the decryption code.

36. The data processing device of claim 35, wherein the processor is configured to communicate with the code provider over a network.

37. The data processing device of claim 36, wherein the processor is configured to generate a decryption key request based on the first and second unique identifiers and to transmit the decryption key request to the code provider over the network.

38. The data processing device of claim 35, wherein the decryption code includes a decryption key and format information and wherein the processor is configured to determine a decryption format of the encrypted data based on the format information and to decrypt the encrypted data based on the decryption key and the decryption format.

39. A data storage medium storing data encoded according to the method of claim 1.
